(19) United States
(12) Patent Application Publication
(10) Pub. No.: US 2009/0021209 A1
(43) Pub. Date: Jan. 22, 2009

(54) POWER SUPPLY ASSEMBLY CAPABLE OF COLLECTING SOLAR POWER

(75) Inventor: Wen-Chang Lin, Kaohsiung Hsien (TW)

Correspondence Address: SHERIDAN ROSS PC, 1560 BROADWAY, SUITE 1200, DENVER, CO, 80202, US

(73) Assignee: YU CHUAN TECHNOLOGY ENTERPRISE CO., LTD., Kaohsiung Hsien (TW)

(21) Appl. No.: 11/779,359

(22) Filed: Jul. 18, 2007

(51) Int. Cl. H02J 7/00; H01L 31/042; H02J 7/02

(52) U.S. Cl. 320/101

(57) ABSTRACT

A power supply assembly includes a case body, a rechargeable battery set disposed in an inner receiving space in the case body, a charging mode selecting unit operable so as to select one of electrical energy converted from solar power by a solar power collecting plate, DC power from an external DC power source, and DC power obtained by converting AC power from an external AC power source to charge the rechargeable battery sets and a power output selecting unit operable so as to output one of the electrical power from the rechargeable battery set and AC power obtained by converting the electrical power from the rechargeable battery set at a corresponding one of AC and DC output ports.

### BACKGROUND OF THE INVENTION

1. Field of the Invention

The invention relates to a power supply, more particularly to a power supply assembly capable of collecting solar power.

2. Description of the Related Art

For outdoor activities, a battery set in a car or a generator utilizing fuel oil is usually used to supply electrical power to electrical appliances. However, the aforesaid battery set and generator have relatively large sizes, thereby making them inconvenient to carry. Moreover, the aforesaid generator easily results in air pollution due to burning of fuel oil.

### SUMMARY OF THE INVENTION

Therefore, the object of the present invention is to provide a power supply assembly that can collect solar power and that has an inner receiving space.

According to the present invention, a power supply assembly comprises:

a case body having an inner receiving space and an outer surface;

a solar power collecting plate mounted on the outer surface of the case body and adapted to convert solar power into electrical energy;

a rechargeable battery set disposed in the inner receiving space;

a DC input port mounted on the outer surface of the case body and adapted to be connected electrically to an external direct current power source;

an AC input port mounted on the outer surface of the case body and adapted to be connected electrically to an external alternating current power source;

an AC-to-DC converter connected electrically to the AC input port and adapted to convert alternating current power from the alternating current power source into direct current power;

a charging mode selecting unit connected electrically to the solar power collecting plate, the DC input port, the AC-to-DC converter and the rechargeable battery set, the charging mode selecting unit being operable in a selected one of a first charging mode, where the direct current power from the AC-to-DC converter is used to charge the rechargeable battery set, a second charging mode, where direct current power from the external direct current power source is used to charge the rechargeable battery set, and a third charging mode, where the electrical energy from the solar power collecting plate is used to charge the rechargeable battery set;

a DC-to-AC converter connected electrically to the rechargeable battery set and converting electrical power from the rechargeable battery set into alternating current power;

an AC output port mounted on the outer surface of the case body;

a DC output port mounted on the outer surface of the case body; and

a power output selecting unit mounted on the outer surface of the case body, and connected electrically to the rechargeable battery set, the DC output port, the DC-to-AC converter and the AC output port, the power output selecting unit being operable in a selected one of a DC output mode, where the electrical power from the rechargeable battery set is outputted at the DC output port, and an AC output mode, where the alternating current power from the DC-to-AC converter is outputted at the AC output port.

### BRIEF DESCRIPTION OF THE DRAWINGS

Other features and advantages of the present invention will become apparent in the following detailed description of the preferred embodiment with reference to the accompanying drawings, of which:

FIG. 1 is a perspective view showing the preferred embodiment of a power supply assembly according to the present invention;

FIG. 2 is a schematic circuit block diagram illustrating the preferred embodiment; and

FIG. 3 is a schematic side view showing a DC input port and an AC input port of the preferred embodiment.

### DETAILED DESCRIPTION OF THE PREFERRED EMBODIMENT

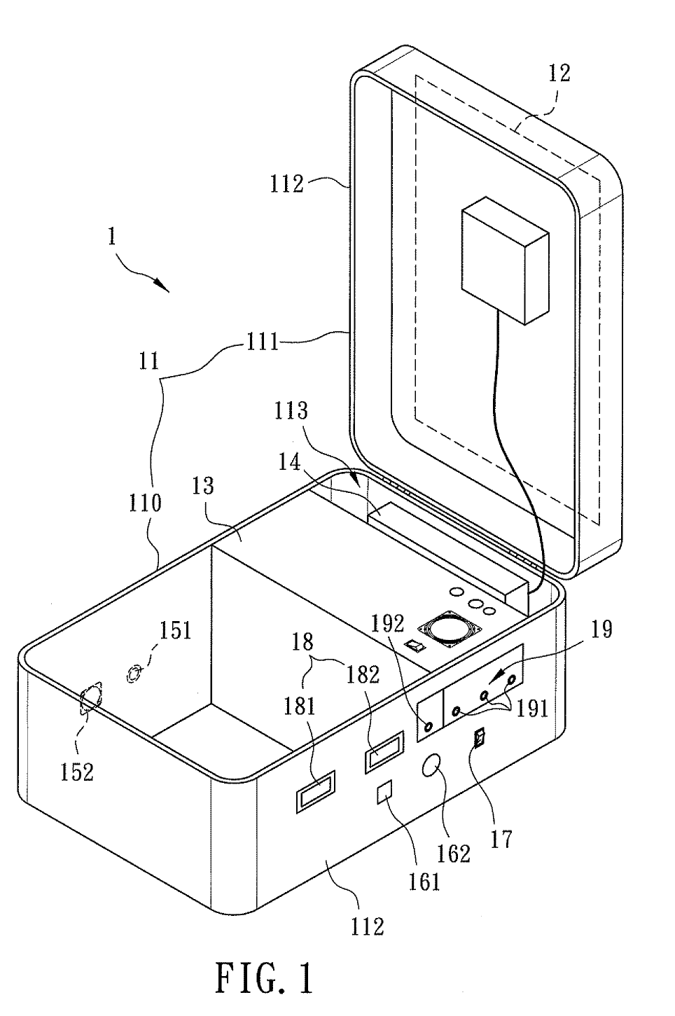

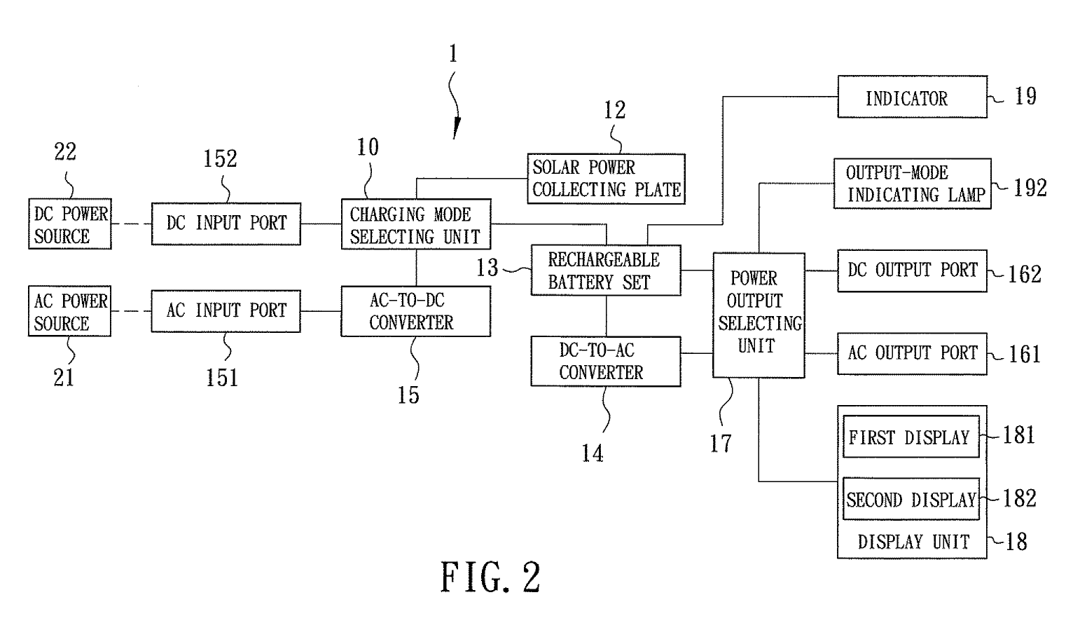

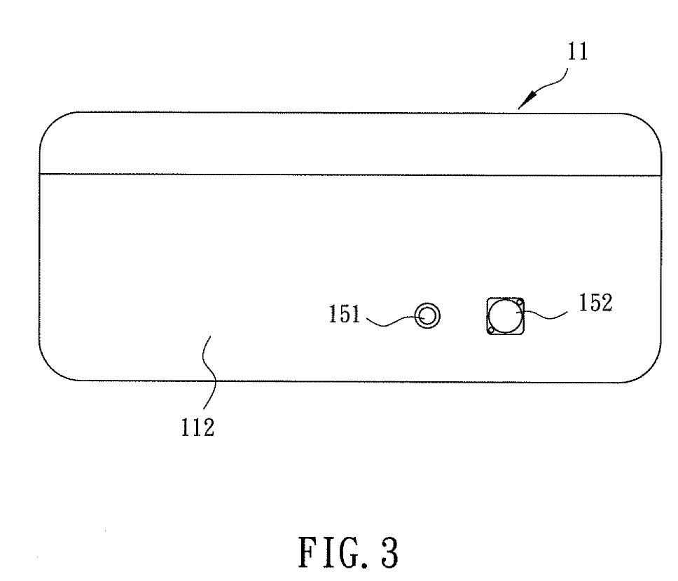

Referring to FIGS. 1 to 3, the preferred embodiment of a power supply assembly 1 according to the present invention is shown to include a case body 11, a solar power collecting plate 12, a rechargeable battery set 13, a DC input port 152, an AC input port 151, an AC-to-DC converter 15, a charging mode selecting unit 10, a DC-to-AC converter 14, an AC output port 161, a DC output port 162, a power output selecting unit 17, a display unit is, and an indicator 19.

The case body 11 consists of complementary lower and upper casing parts 110, 111 connected pivotally to each other, and has an inner receiving space 113 and an outer surface 112.

The solar power collecting plate 12 is mounted on the outer surface 112 of the case body 11, and is adapted to convert solar power into electrical energy.

The rechargeable battery set 13 is disposed in the inner receiving space 113 in the case body 11. In this embodiment, the rechargeable battery set 13 includes a lithium battery. In other embodiments, the rechargeable battery set 13 may include a carbon-hydrogen battery.

The DC input port 152 is mounted on the outer surface 112 of the case body 11, and is adapted to be connected electrically to an external direct current (DC) power source 22.

The AC input port 151 is mounted on the outer surface 112 of the case body 11, and is adapted to be connected electrically to an external alternating current (AC) power source 21. The AC-to-DC converter 15 connected electrically to the AC input port 151 and is adapted to convert AC power from the AC power source 21 into DC power.

The charging mode selecting unit 10 is connected electrically to the solar power collecting plate 12, the DC input port 152, the AC-to-DC converter 15 and the rechargeable battery set 13. The charging mode selecting unit 17 is operable in a selected one of a first charging mode, where the DC power from the AC-to-AC converter 15 is used to charge the rechargeable battery set 13, a second charging mode, where DC power from the external DC power source 22 is used to charge the rechargeable battery set 13, and a third charging mode, where the electrical energy from the solar power collecting plate 12 is used to charge the rechargeable battery set 13.

The DC-to-AC converter 14 is connected electrically to the rechargeable battery set 13, and converts electrical power from the rechargeable battery set 13 into AC power.

The AC output port 161 is mounted on the outer surface 112 of the case body 11.

The DC output port 162 is mounted on the outer surface 112 of the case body 11.

The power output selecting unit 17 is mounted on the outer surface 112 of the case body 11, and is connected electrically to the rechargeable battery set 13, the DC output port 162, the DC-to-AC converter 14 and the AC output port 161. The power output selecting unit 17 is operable in a selected one of a DC output mode, where the electrical power from the rechargeable battery set 13 is outputted at the DC output port 162, and an AC output mode, where the AC power from the DC-to-AC converter 14 is outputted at the AC output port 161.

The display unit 18 is mounted on the outer surface 112 of the case body 11, is connected electrically to the power output selecting unit 17, and displays electrical power information of electrical power outputted at the DC output port 162 and the AC output port 161. In this embodiment, the display unit 18 includes a first display 181 for displaying the electrical power information of the electrical power outputted at the AC output port 161, and a second display 182 for displaying the electrical power information of the electrical power outputted at the DC output port 162.

The indicator 19 is mounted on the outer surface 112 of the case body 11 for indicating amount of the electrical power stored in the rechargeable battery set 13. In this embodiment, the indicator 19 includes a plurality of aligned indicating lamps 191 corresponding respectively to different power storage conditions for the rechargeable battery set 13, such as a high level, a medium level and a low level. One of the indicating lamps 191 corresponding to the amount of the electrical power stored in the rechargeable battery set 13 is lighted.

The power supply assembly 1 further includes an output-mode indicating lamp 192 that is mounted on the outer surface 112 of the case body 11 and that is activated to emit light when the power output selecting unit 17 is switched to the AC output mode.

In sum, aside from being capable of collecting solar power, since the case body 11 is portable and is configured with the inner receiving space 113, the power supply assembly 1 of this invention can also serve as a storage case, thereby facilitating outdoor use.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

I claim:

1. A power supply assembly comprising:
a case body having an inner receiving space and an outer surface;
a solar power collecting plate mounted on said outer surface of said case body and adapted to convert solar power into electrical energy;
a rechargeable battery set disposed in said inner receiving space;
a DC input port mounted on said outer surface of said case body and adapted to be connected electrically to an external direct current power source;
an AC input port mounted on said outer surface of said case body and adapted to be connected electrically to an external alternating current power source;
an AC-to-DC converter connected electrically to said AC input port and adapted to convert alternating current power from the alternating current power source into direct current power;
a charging mode selecting unit connected electrically to said solar power collecting plate, said DC input port, said AC-to-DC converter and said rechargeable battery set, said charging mode selecting unit being operable in a selected one of a first charging mode, where the direct current power from said AC-to-DC converter is used to charge said rechargeable battery set, a second charging mode, where direct current power from the external direct current power source is used to charge said rechargeable battery set, and a third charging mode, where the electrical energy from said solar power collecting plate is used to charge said rechargeable battery set;
a DC-to-AC converter connected electrically to said rechargeable battery set and converting electrical power from said rechargeable battery set into alternating current power;
an AC output port mounted on said outer surface of said case body;
a DC output port mounted on said outer surface of said case body; and
a power output selecting unit mounted on said outer surface of said case body, and connected electrically to said rechargeable battery set, said DC output port, said DC-to-AC converter and said AC output port, said power output selecting unit being operable in a selected one of a DC output mode, where the electrical power from said rechargeable battery set is outputted at said DC output port, and an AC output mode, where the alternating current power from said DC-to-AC converter is outputted at said AC output port.

2. The power supply assembly as claimed in claim 1, further comprising a display unit mounted on said outer surface of said case body for displaying electrical power information of electrical power outputted at said DC output port and said AC output port.

3. The power supply assembly as claimed in claim 2, wherein said display unit includes a first display for displaying the electrical power information of the electrical power outputted at said AC output port, and a second display for displaying the electrical power information of the electrical power outputted at said DC output port.

4. The power supply assembly as claimed in claim 1, further comprising an indicator mounted on said outer surface of said case body for indicating amount of the electrical power stored in said rechargeable battery set.

5. The power supplying assembly as claimed in claim 4, wherein said indicator includes a plurality of aligned indicating lamps corresponding respectively to different power storage conditions for the rechargeable battery set, one of said indicating lamps corresponding to the amount of the electrical power stored in said rechargeable battery set being lighted.

6. The power supply assembly as claimed in claim 1, further comprising an output-mode indicating lamp mounted on said outer surface of said case body and activated to emit light when said power output selecting unit is switched to the AC output mode.

7. The power supply assembly as claimed in claim 1, wherein said rechargeable battery set includes a lithium battery.

8. The power supply assembly as claimed in claim 1, wherein said rechargeable battery set includes a carbon-hydrogen battery.
